(19) United States
(12) Patent Application Publication
(10) Pub. No.: US 2026/0231719 A1
(43) Pub. Date: Aug. 6, 2026

(54) SUBSTRATE PROCESSING METHOD AND SUBSTRATE PROCESSING APPARATUS FOR HEATING SUBSTRATE BY LIGHT IRRADIATION

(71) Applicant: SCREEN Holdings Co., Ltd., Kyoto (JP)

(72) Inventors: Oma NAKAJIMA, Kyoto-shi (JP); Hiroyasu TAKEHARA, Kyoto-shi (JP)

(21) Appl. No.: 19/449,363

(22) Filed: Jan. 14, 2026

(30) Foreign Application Priority Data
Feb. 4, 2025 (JP) 2025-016944

(51) Int. Cl. H10P 72/00

(52) U.S. Cl. CPC H10P 72/0436; H10P 72/0402; H10P 72/0604

(57) ABSTRACT

A treatment chamber for performing a heating treatment on a semiconductor wafer and a transport chamber for housing a transport robot are connected to each other via a gate valve and an O-ring. If the O-ring breaks while pressure in the treatment chamber is reduced during the heating treatment of the semiconductor wafer, there is a danger that an atmosphere in the transport chamber is sucked in by the treatment chamber to result in an abrupt pressure drop in the transport chamber. The pressure of the gas in the transport chamber is monitored during the execution of the heating treatment of the semiconductor wafer in the treatment chamber. If the pressure in the transport chamber falls to not greater than a predetermined threshold value, the heating treatment is interrupted, and the pressures in the treatment chamber and the transport chamber are returned to atmospheric pressure.

### BACKGROUND

### Technical Field

The present invention relates to a substrate processing method and a substrate processing apparatus which irradiate a substrate with light to heat the substrate. Examples of the substrate to be processed include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term "flash lamp" as used hereinafter refers to a "xenon flash lamp") are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only the activation of the impurities without deep diffusion of the impurities.

The flash lamp annealing such as for impurity activation is performed in an atmosphere of atmospheric pressure. However, depending on the details of the process, the flash lamp annealing is performed in some cases while supplying a specific treatment gas (e.g., ammonia, ozone, or the like) in a reduced-pressure atmosphere in which the pressure in a treatment chamber is reduced to, for example, approximately 5 to 50 kPa. Japanese Patent Application Laid-Open No. 2020-123602 discloses a technique for performing PDA (Post Deposition Anneal) on a high dielectric constant film by irradiating a semiconductor wafer with a flash of light in an ammonia atmosphere in which the pressure in a treatment chamber is reduced to 5 kPa.

Japanese Patent Application Laid-Open No. 2020-123602 also discloses that a transport chamber for housing a transport robot and a treatment chamber for performing flash irradiation are connected to each other, so that the transport robot transports a semiconductor wafer into and out of the treatment chamber. A transport opening which connects the transport chamber and the treatment chamber is opened and closed by a gate valve. When the transport opening is closed by the gate valve, an O-ring maintains the hermeticity of the treatment chamber to prevent ammonia and the like from leaking out of the treatment chamber.

The pressure in the transport chamber is normally maintained at atmospheric pressure. However, if the O-ring of the gate valve breaks while the pressure in the treatment chamber is reduced, the pressure in the transport chamber is also abruptly reduced, which in turn results in problems such as breakage of a quartz window provided in the transport chamber.

When problems as described above occur, it is necessary to suspend the treatment, retrieve the semiconductor wafer being treated, and then perform maintenance. The retrieval of the semiconductor wafer from the treatment chamber necessitates the opening of the gate valve. At this time, however, there is a danger that a hazardous gas such as ammonia is released from the treatment chamber.

### SUMMARY

The present invention is intended for a method of heating a substrate by irradiating the substrate with light.

According to one aspect of the present invention, the method comprises: (a) transporting a substrate into a treatment chamber connected via a gate valve and an O-ring to a transport chamber for housing a transport robot; (b) irradiating the substrate with light to perform a heating treatment while pressure in the treatment chamber which receives the substrate therein is reduced to less than atmospheric pressure and a predetermined reactive gas atmosphere is formed in the treatment chamber; (c) detecting whether pressure in the transport chamber is greater than a first threshold value less than atmospheric pressure or not during the execution of the (b); and (d) stopping an exhaust pump for reducing the pressure in the treatment chamber and supplying an inert gas into the treatment chamber to return the pressure in the treatment chamber to atmospheric pressure, when it is detected that the pressure in the transport chamber is not greater than the first threshold value.

The pressure difference between the treatment chamber and the transport chamber is decreased. This prevents an abrupt pressure drop in the transport chamber to mitigate problems resulting from breakage of the O-ring which connects the chambers.

Preferably, when it is detected that the pressure in the transport chamber is not greater than the first threshold value, the inert gas is further supplied into the transport chamber to return the pressure in the transport chamber to atmospheric pressure.

The pressure difference between the treatment chamber and the transport chamber is further decreased.

Preferably, the method further comprises (e) measuring the concentration of the reactive gas remaining in the treatment chamber after the pressure in the treatment chamber is returned to atmospheric pressure in the (d), wherein the gate valve is permitted to open if the concentration of the reactive gas in the treatment chamber is not greater than a predetermined value.

The reactive gas is prevented from leaking from the treatment chamber into the transport chamber.

The present invention is also intended for a substrate processing apparatus for heating a substrate by irradiating the substrate with light.

According to one aspect of the present invention, the substrate processing apparatus comprises: a transport chamber for housing a transport robot; a treatment chamber connected via a gate valve and an O-ring to the transport chamber; a first gas supply part for supplying a predetermined reactive gas or inert gas to the treatment chamber; an exhaust part including an exhaust pump for exhausting a gas from the treatment chamber to reduce pressure in the treatment chamber; a light irradiator for irradiating a substrate received in the treatment chamber with light; a first pressure gauge for measuring the pressure in the treatment chamber; a second pressure gauge for measuring pressure in the transport chamber; and a controller for controlling the first gas supply part and the exhaust part, wherein, when it is detected that the pressure in the transport chamber measured by the second pressure gauge is not greater than a first threshold value less than atmospheric pressure during the execution of a heating treatment that irradiates the substrate with light while the pressure in the treatment chamber which receives the substrate therein is reduced to less than atmospheric pressure and an atmosphere of the reactive gas is formed in the treatment chamber, the controller stops the exhaust pump and controls the first gas supply part so as to supply the inert gas into the treatment chamber to thereby return the pressure in the treatment chamber to atmospheric pressure.

The pressure difference between the treatment chamber and the transport chamber is decreased. This prevents an abrupt pressure drop in the transport chamber to mitigate problems resulting from breakage of the O-ring which connects the chambers.

Preferably, the substrate processing apparatus further comprises a second gas supply part for supplying an inert gas to the transport chamber, wherein, when it is detected that the pressure in the transport chamber is not greater than the first threshold value, the controller controls the second gas supply part so as to supply the inert gas into the transport chamber to thereby return the pressure in the transport chamber to atmospheric pressure.

The pressure difference between the treatment chamber and the transport chamber is further decreased.

Preferably, the substrate processing apparatus further comprises a first gas detector for measuring the concentration of the reactive gas in the treatment chamber, wherein the gate valve is permitted to open if the concentration of the reactive gas remaining in the treatment chamber is not greater than a predetermined value after the pressure in the treatment chamber is returned to atmospheric pressure.

The reactive gas is prevented from leaking from the treatment chamber into the transport chamber.

It is therefore an object of the present invention to mitigate problems resulting from breakage of an O-ring which connects chambers.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a substrate processing apparatus according to the present invention;

FIG. 2 is a front view of the substrate processing apparatus of FIG. 1:

FIG. 3 is a longitudinal sectional view showing a configuration of a heat treatment part;

FIG. 4 is a perspective view showing the entire external appearance of a holder;

FIG. 5 is a plan view of a susceptor;

FIG. 6 is a sectional view of the susceptor;

FIG. 7 is a plan view of a transfer mechanism;

FIG. 8 is a side view of the transfer mechanism;

FIG. 9 is a plan view showing an arrangement of halogen lamps;

FIG. 10 is a diagram schematically showing supply and exhaust mechanisms for a treatment chamber and a transport chamber;

FIG. 11 is a block diagram showing a configuration of a controller;

FIG. 12 is a flow diagram showing a procedure for pressure control in the case of breakage of an O-ring;

FIG. 13 is a flow diagram showing a procedure for a residual gas check in the treatment chamber;

FIG. 14 is a view showing an example of a GUI appearing on a display part during the residual gas check;

FIG. 15 is a view showing an example of the GUI appearing on the display part during a concentration measurement waiting period; and

FIG. 16 is a view showing an example of the GUI appearing on the display part when the opening of a gate valve is permitted.

### DESCRIPTION OF THE PREFERRED EMBODIMENTS

A preferred embodiment according to the present invention will now be described in detail with reference to the drawings. In the following description, expressions indicating relative or absolute positional relationships (e.g., "in one direction", "along one direction", "parallel", "orthogonal", "center", "concentric", and "coaxial") shall represent not only the exact positional relationships but also a state in which the angle or distance is relatively displaced to the extent that tolerances or similar functions are obtained, unless otherwise specified. Also, expressions indicating equal states (e.g., "identical", "equal", and "homogeneous") shall represent not only a state of quantitative exact equality but also a state in which there are differences that provide tolerances or similar functions, unless otherwise specified. Also, expressions indicating shapes (e.g., "circular", "rectangular", and "cylindrical") shall represent not only the geometrically exact shapes but also shapes to the extent that the same level of effectiveness is obtained, unless otherwise specified, and may have unevenness or chamfers. Also, an expression such as "comprising", "equipped with", "provided with", "including", or "having" a component is not an exclusive expression that excludes the presence of other components. Also, the expression "at least one of A, B, and C" includes "A only", "B only", "C only", "any two of A, B, and C", and "all of A, B, and C".

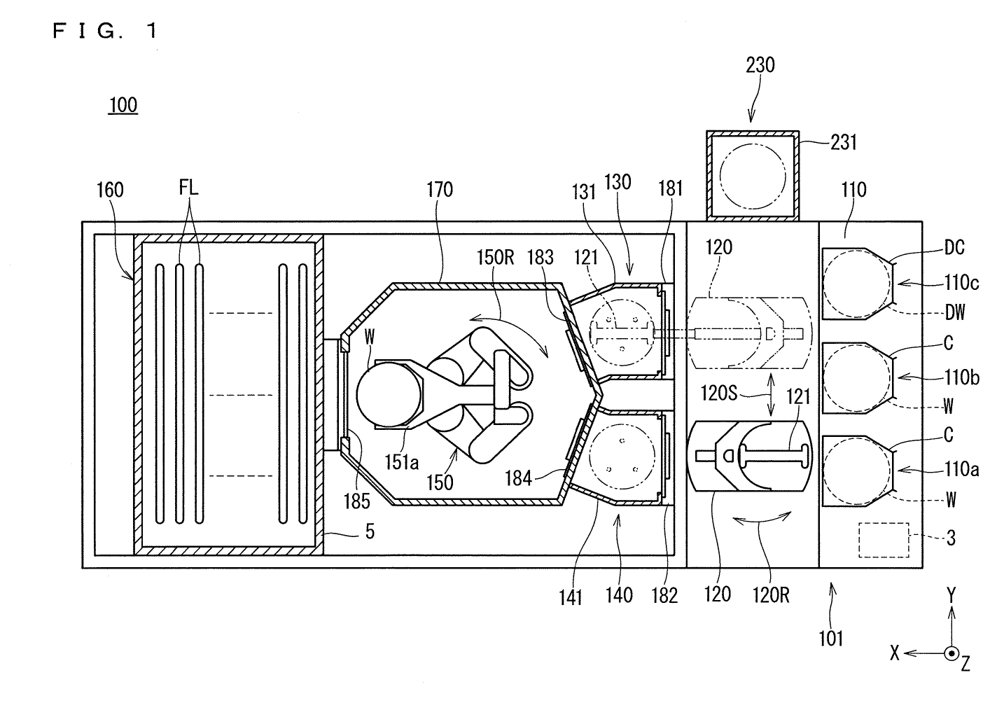

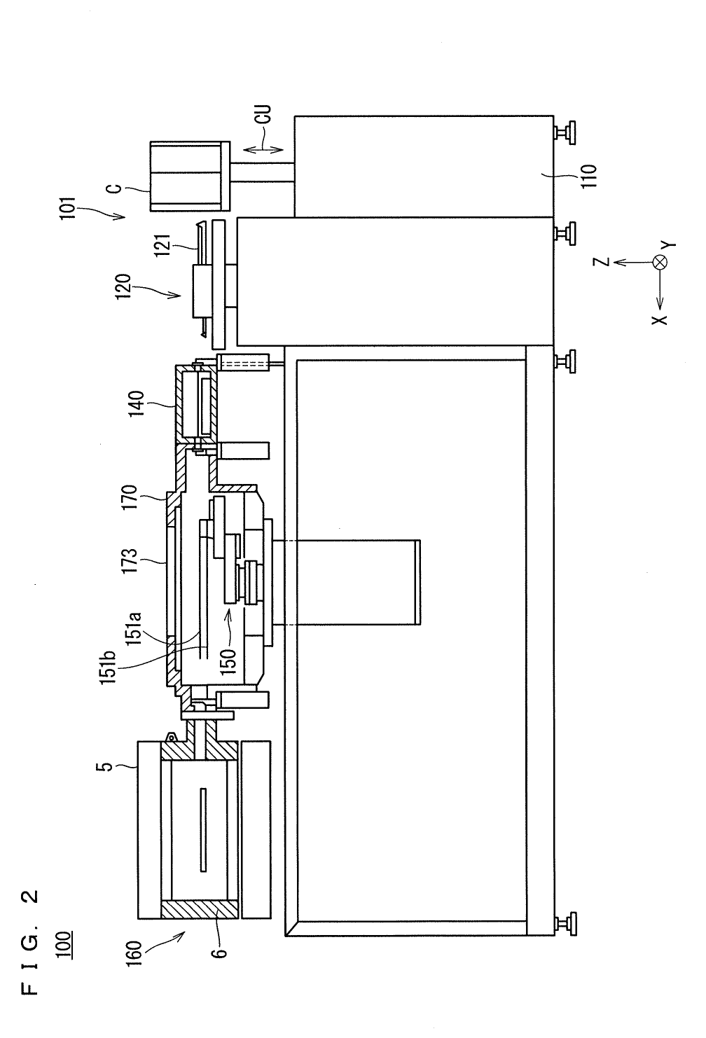

First, an example of the configuration of a substrate processing apparatus according to the present invention will be described. FIG. 1 is a plan view of a substrate processing apparatus 100 according to the present invention, and FIG. 2 is a front view of the substrate processing apparatus 100. The substrate processing apparatus 100 is a flash lamp annealer for irradiating a disk-shaped semiconductor wafer W serving as a substrate with flashes of light to heat the semiconductor wafer W. The size of the semiconductor wafer W to be processed is not particularly limited. For example, the semiconductor wafer W to be processed has a diameter of 300 mm and 450 mm. It should be noted that the dimensions of components and the number of components are shown in exaggeration or in simplified form, as appropriate, in FIG. 1 and the subsequent figures for the sake of easier understanding. An XYZ rectangular coordinate system in which an XY plane is defined as a horizontal plane and a Z axis is defined to extend in a vertical direction is additionally shown in FIGS. 1 to 3 for purposes of clarifying the directional relationship therebetween.

As shown in FIGS. 1 and 2, the substrate processing apparatus 100 includes: an indexer part 101 for transporting unprocessed semiconductor wafers W from the outside into the substrate processing apparatus 100 and for transporting processed semiconductor wafers W to the outside of the substrate processing apparatus 100; an alignment part 230 for positioning an unprocessed semiconductor wafer W; a first cooling part 130 and a second cooling part 140 each for cooling a semiconductor wafer W subjected to heating treatment; a heat treatment part 160 for performing flash heating treatment on a semiconductor wafer W; and a transport robot 150 for transferring a semiconductor wafer W to and from the first cooling part 130, the second cooling part 140, and the heat treatment part 160. The substrate processing apparatus 100 further includes a controller 3 for controlling operating mechanisms provided in the aforementioned processing parts and the transport robot 150 to cause the flash heating treatment of the semiconductor wafer W to proceed.

The indexer part 101 includes: a load port 110 for placing thereon a plurality of carriers (or cassettes) C arranged in juxtaposition; and a transfer robot 120 for taking an unprocessed semiconductor wafer W out of each of the carriers C and for storing a processed semiconductor wafer W into each of the carriers C. To be precise, the indexer part 101 includes three load ports, and the load port 110 is a collective designation for a first load port 110a, a second load port 110b, and a third load port 110c. (The three load ports 110a, 110b, and 110c are collectively referred to as the load port 110, unless otherwise identified.) Carriers C in which semiconductor wafers W (product wafers) that become products are stored are placed on the first load port 110a and the second load port 110b. On the other hand, the third load port 110c is a load port exclusive to a dummy carrier DC in which dummy wafers DW are stored. That is, only the dummy carrier DC is placed on the third load port 110c. The dummy wafers DW are wafers having the same shape and material as the product wafers but are not processed as products.

An unmanned transport vehicle (an AGV (automatic guided vehicle) or an OHT (overhead hoist transfer)) or the like transports a carrier C with unprocessed semiconductor wafers W stored therein and the dummy carrier DC to place the carrier C and the dummy carrier DC on the load port 110. The carriers C and the dummy carrier DC are tagged for identification, and the tags on the carriers C and the dummy carrier DC placed on the load port 110 are read by a tag reader not shown. The unmanned transport vehicle also carries a carrier C with processed semiconductor wafers W stored therein and the dummy carrier DC away from the load port 110.

In the load port 110, the carriers C and the dummy carrier DC are movable upwardly and downwardly as indicated by an arrow CU in FIG. 2 so that the transfer robot 120 is able to load any semiconductor wafer W (or any dummy wafer DW) into each of the carriers C and the dummy carrier DC and unload any semiconductor wafer W (or any dummy wafer DW) from each of the carriers C and the dummy carrier DC. The carriers C and the dummy carrier DC may be of the following types: an SMIF (standard mechanical interface) pod and an OC (open cassette) which exposes stored semiconductor wafer W to the outside atmosphere, in addition to a FOUP (front opening unified pod) which stores semiconductor wafer W in an enclosed or sealed space.

The transfer robot 120 is slidable as indicated by an arrow 120S in FIG. 1, pivotable as indicated by an arrow 120R in FIG. 1, and movable upwardly and downwardly. Thus, the transfer robot 120 loads and unloads semiconductor wafers W into and from the carriers C and the dummy carrier DC, and transfers semiconductor wafers W to and from the alignment part 230 and the two cooling parts (the first cooling part 130 and the second cooling part 140). The operation of the transfer robot 120 loading and unloading the semiconductor wafers W into and from the carriers C (or the dummy carrier DC) is achieved by the sliding movement of a hand 121 of the transfer robot 120 and the upward and downward movement of the carriers C. The transfer of the semiconductor wafers W between the transfer robot 120 and the alignment part 230, between the transfer robot 120 and the first cooling part 130, or between the transfer robot 120 and the second cooling part 140 is achieved by the sliding movement of the hand 121 and the upward and downward movement of the transfer robot 120.

The alignment part 230 is provided on and connected to one side of the indexer part 101 in adjacent relation thereto along the Y axis. The alignment part 230 is a processing part for rotating a semiconductor wafer W in a horizontal plane to an orientation appropriate for flash heating. The alignment part 230 includes an alignment chamber 231 which is a housing made of an aluminum alloy, a mechanism provided in the alignment chamber 231 and for supporting and rotating a semiconductor wafer W in a horizontal attitude, a mechanism provided in the alignment chamber 231 and for optically detecting a notch, an orientation flat, and the like formed in a peripheral portion of a semiconductor wafer W, and the like.

The transfer robot 120 transfers a semiconductor wafer W to and from the alignment part 230. The semiconductor wafer W is transferred from the transfer robot 120 to the alignment chamber 231 so that the center of the semiconductor wafer W is positioned at a predetermined position. The alignment part 230 rotates the semiconductor wafer W received from the indexer part 101 about a vertical axis passing through the central portion of the semiconductor wafer W to optically detect a notch and the like, thereby adjusting the orientation of the semiconductor wafer W. The semiconductor wafer W subjected to the orientation adjustment is taken out of the alignment chamber 231 by the transfer robot 120.

A transport chamber 170 for housing the transport robot 150 therein is provided as space for transport of the semiconductor wafer W by means of the transport robot 150. A treatment chamber 6 in the heat treatment part 160, a first cool chamber 131 in the first cooling part 130, and a second cool chamber 141 in the second cooling part 140 are connected to three sides of the transport chamber 170. The transport chamber 170 is provided with a quartz window 173 for visual recognition of the operation of the transport robot 150.

The heat treatment part 160 which is a principal part of the substrate processing apparatus 100 is a substrate processing part for irradiating a preheated semiconductor wafer W with flashes of light from xenon flash lamps FL to perform flash heating treatment on the semiconductor wafer W. The configuration of the heat treatment part 160 will be described later in detail.

The first cooling part 130 and the second cooling part 140 are substantially similar in configuration to each other. The first and second cooling parts 130 and 140 include respective metal cooling plates and respective quartz plates (both not shown) placed on the upper surfaces of the cooling plates in the first and second cool chambers 131 and 141 which are housings made of an aluminum alloy. Each of the cooling plates is temperature-controlled at ordinary temperatures (approximately 23°C) by a Peltier element or by circulation of constant-temperature water. The semiconductor wafer W subjected to the flash heating treatment in the heat treatment part 160 is transported into the first cool chamber 131 or the second cool chamber 141, and is then placed and cooled on a corresponding one of the quartz plate.

The first cool chamber 131 and the second cool chamber 141 provided between the indexer part 101 and the transport chamber 170 are connected to both the indexer part 101 and the transport chamber 170. Each of the first cool chamber 131 and the second cool chamber 141 has two openings for transporting the semiconductor wafer W thereinto and therefrom. One of the openings of the first cool chamber 131 which is connected to the indexer part 101 is openable and closable by a gate valve 181. The other opening of the first cool chamber 131 which is connected to the transport chamber 170 is openable and closable by a gate valve 183. In other words, the first cool chamber 131 and the indexer part 101 are connected to each other through the gate valve 181, and the first cool chamber 131 and the transport chamber 170 are connected to each other through the gate valve 183.

The gate valve 181 is opened when the semiconductor wafer W is transferred between the indexer part 101 and the first cool chamber 131. The gate valve 183 is opened when the semiconductor wafer W is transferred between the first cool chamber 131 and the transport chamber 170. When the gate valve 181 and the gate valve 183 are closed, the interior of the first cool chamber 131 is an enclosed space.

One of the two openings of the second cool chamber 141 which is connected to the indexer part 101 is openable and closable by a gate valve 182. The other opening of the second cool chamber 141 which is connected to the transport chamber 170 is openable and closable by a gate valve 184. In other words, the second cool chamber 141 and the indexer part 101 are connected to each other through the gate valve 182, and the second cool chamber 141 and the transport chamber 170 are connected to each other through the gate valve 184.

The gate valve 182 is opened when the semiconductor wafer W is transferred between the indexer part 101 and the second cool chamber 141. The gate valve 184 is opened when the semiconductor wafer W is transferred between the second cool chamber 141 and the transport chamber 170. When the gate valve 182 and the gate valve 184 are closed, the interior of the second cool chamber 141 is an enclosed space. The volume of the first cool chamber 131 and the second cool chamber 141 is smaller than that of the transport chamber 170, and is approximately 1/10 that of the transport chamber 170.

The transport robot 150 provided in the transport chamber 170 is pivotable about a vertical axis as indicated by an arrow 150R. The transport robot 150 includes two linkage mechanisms comprised of a plurality of arm segments. Transport hands 151a and 151b each for holding a semiconductor wafer W are provided at respective distal ends of the two linkage mechanisms. These transport hands 151a and 151b are vertically spaced a predetermined distance apart from each other, and are independently linearly slidable in the same horizontal direction by the respective linkage mechanisms. The transport robot 150 moves a base provided with the two linkage mechanisms upwardly and downwardly to thereby move the two transport hands 151a and 151b spaced the predetermined distance apart from each other upwardly and downwardly.

When the transport robot 150 transfers (loads and unloads) a semiconductor wafer W to and from the first cool chamber 131, the second cool chamber 141, or the treatment chamber 6 in the heat treatment part 160 as a transfer target, both of the transport hands 151a and 151b pivot into opposed relation to the transfer target, and move upwardly or downwardly after (or during) the pivotal movement, so that one of the transport hands 151a and 151b reaches a vertical position at which the semiconductor wafer W is to be transferred to and from the transfer target. Then, the transport robot 150 causes the transport hand 151a (or 151b) to linearly slide in a horizontal direction, thereby transferring the semiconductor wafer W to and from the transfer target.

The transfer of a semiconductor wafer W between the transport robot 150 and the transfer robot 120 is performed through the first cooling part 130 or the second cooling part 140. That is, the first cool chamber 131 in the first cooling part 130 and the second cool chamber 141 in the second cooling part 140 function also as paths for transferring a semiconductor wafer W between the transport robot 150 and the transfer robot 120. Specifically, one of the transport robot 150 and the transfer robot 120 transfers a semiconductor wafer W to the first cool chamber 131 or the second cool chamber 141, and the other of the transport robot 150 and the transfer robot 120 receives the semiconductor wafer W, whereby the transfer of the semiconductor wafer W is performed. The transport robot 150 and the transfer robot 120 constitute a transport mechanism for transporting a semiconductor wafer W from the carriers C to the heat treatment part 160.

As mentioned above, the gate valves 181 and 182 are provided between the indexer part 101 and the first and second cool chambers 131 and 141, respectively. The gate valves 183 and 184 are provided between the transport chamber 170 and the first and second cool chambers 131 and 141, respectively. A gate valve 185 is further provided between the transport chamber 170 and the treatment chamber 6 of the heat treatment part 160. These gate valves 181 to 185 are opened and closed, as appropriate, when the semiconductor wafer W is transported in the substrate processing apparatus 100.

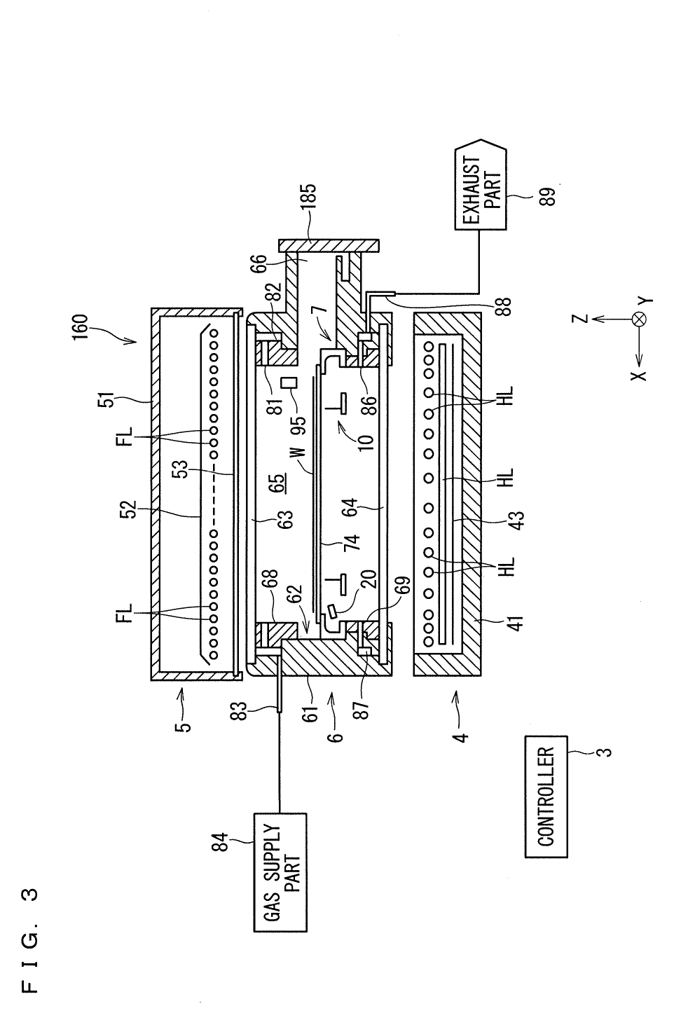

Next, the configuration of the heat treatment part 160 will be described. FIG. 3 is a longitudinal sectional view showing the configuration of the heat treatment part 160. The heat treatment part 160 includes the treatment chamber 6 for receiving a semiconductor wafer W therein to perform heating treatment on the semiconductor wafer W, a flash lamp house 5 including the plurality of built-in flash lamps FL, and a halogen lamp house 4 including a plurality of built-in halogen lamps HL. The flash lamp house 5 is provided over the treatment chamber 6, and the halogen lamp house 4 is provided under the treatment chamber 6. The heat treatment part 160 further includes a holder 7 provided inside the treatment chamber 6 and for holding a semiconductor wafer W in a horizontal attitude, and a transfer mechanism 10 provided inside the treatment chamber 6 and for transferring a semiconductor wafer W between the holder 7 and the transport robot 150.

The treatment chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the treatment chamber 6 is a disk-shaped member made of quartz, and serves as a quartz window that transmits flashes of light emitted from the flash lamps FL therethrough into the treatment chamber 6. The lower chamber window 64 forming the floor of the treatment chamber 6 is also a disk-shaped member made of quartz, and serves as a quartz window that transmits light emitted from the halogen lamps HL therethrough into the treatment chamber 6. The quartz window 173 provided in the transport chamber 170 is significantly thinner as compared with the upper chamber window 63 and the lower chamber window 64.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the treatment chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the treatment chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the treatment chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the treatment chamber 6. The transport opening 66 is openable and closable by the gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the treatment chamber 6 is an enclosed space.

At least one gas supply opening 81 for supplying a treatment gas therethrough into the heat treatment space 65 is provided in an upper portion of the inner wall of the treatment chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the treatment chamber 6. The gas supply pipe 83 is connected to a gas supply part 84. The gas supply part 84 feeds the treatment gas through the gas supply pipe 83 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas include inert gases such as nitrogen gas (N₂), and reactive gases such as ozone (O₃), hydrogen (H₂) and ammonia (NH₃).

At least one gas exhaust opening 86 for exhausting a gas from the heat treatment space 65 is provided in a lower portion of the inner wall of the treatment chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the treatment chamber 6. The gas exhaust pipe 88 is connected to an exhaust part 89. The exhaust part 89 exhausts the gas in the heat treatment space 65 through the gas exhaust opening 86. The at least one gas supply opening 81 and the at least one gas exhaust opening 86 may include a plurality of gas supply openings 81 and a plurality of gas exhaust openings 86, respectively, arranged in a circumferential direction of the treatment chamber 6, and may be in the form of slits. The gas supply part 84 and the exhaust part 89 in the heat treatment part 160 will be described in detail later.

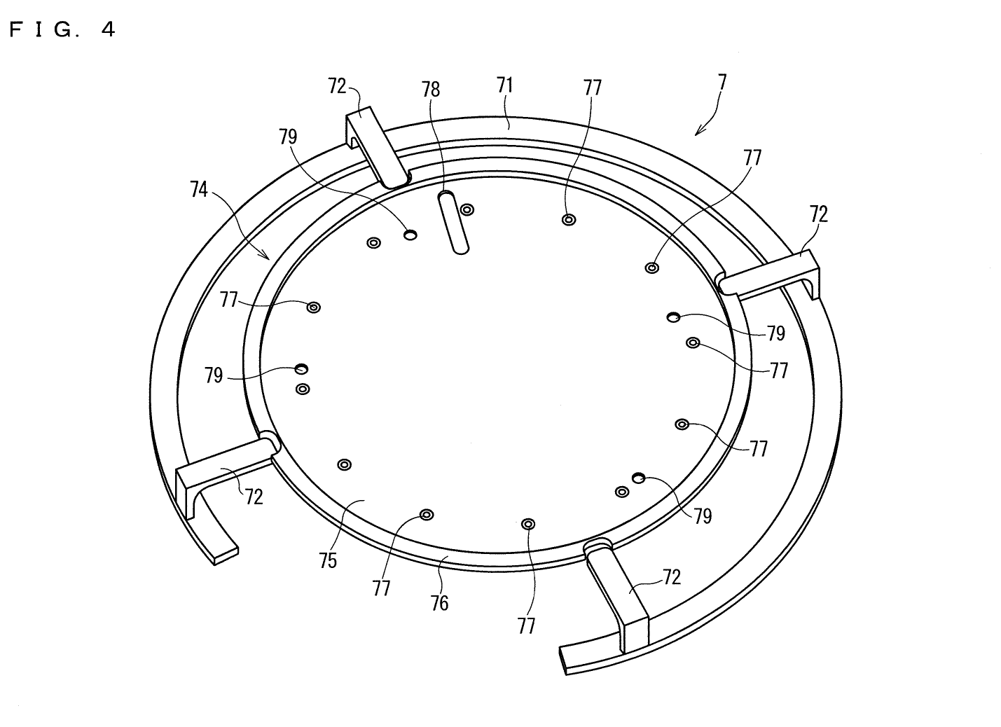

FIG. 4 is a perspective view showing the entire external appearance of the holder 7. The holder 7 includes a base ring 71, coupling portions 72, and a susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the treatment chamber 6 by being placed on the bottom surface of the recessed portion 62 (with reference to FIG. 3). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

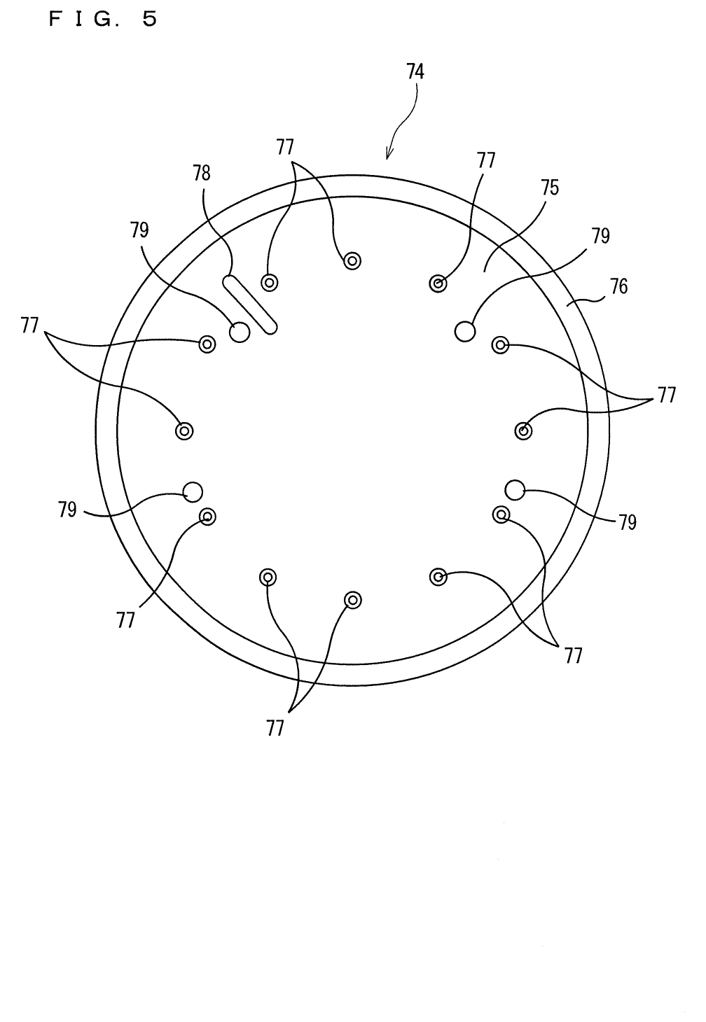

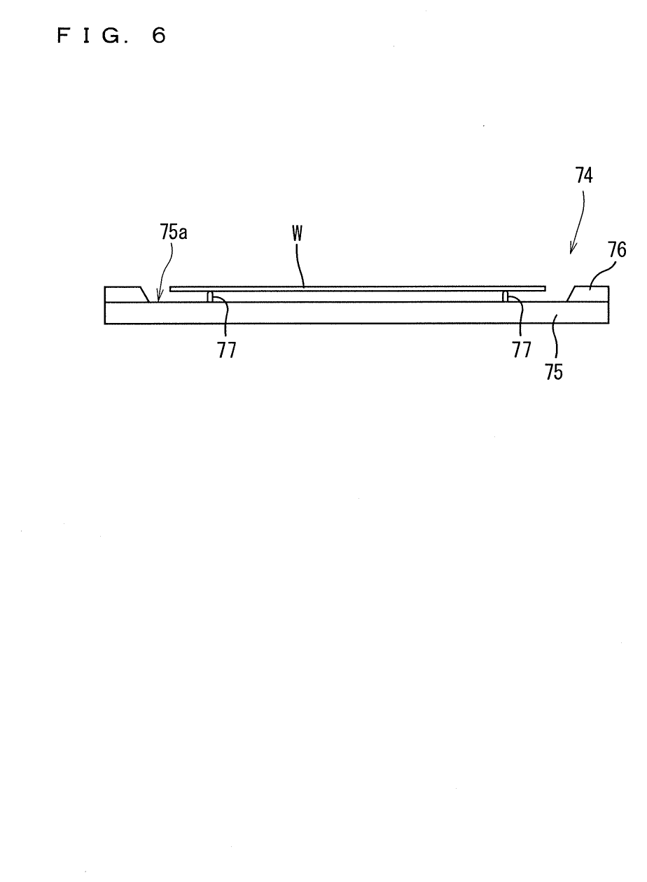

The susceptor 74 is supported by the four coupling portions 72 provided on the base ring 71. FIG. 5 is a plan view of the susceptor 74. FIG. 6 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 4, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the treatment chamber 6, whereby the holder 7 is mounted to the treatment chamber 6. With the holder 7 mounted to the treatment chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the treatment chamber 6 is placed and held in a horizontal attitude on the susceptor 74 of the holder 7 mounted to the treatment chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 4 and 5, an opening 78 is provided in the holding plate 75 of the susceptor 74 so as to extend vertically through the holding plate 75 of the susceptor 74. The opening 78 is provided for a radiation thermometer 20 (with reference to FIG. 3) to receive radiation (infrared radiation) emitted from the lower surface of the semiconductor wafer W held by the susceptor 74. Specifically, the radiation thermometer 20 receives the radiation emitted from the lower surface of the semiconductor wafer W held by the susceptor 74 through the opening 78 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

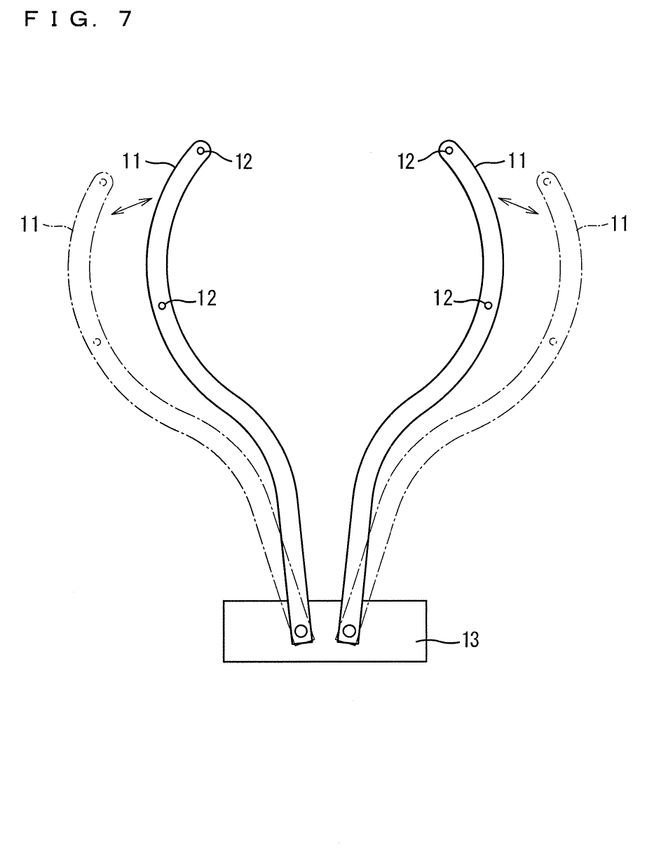

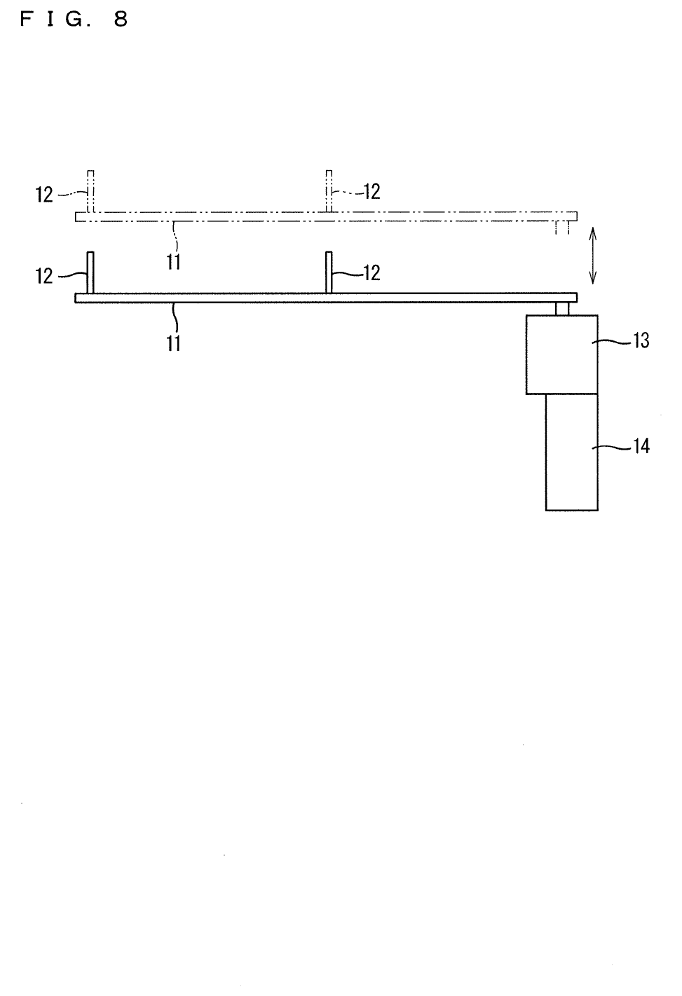

FIG. 7 is a plan view of the transfer mechanism 10. FIG. 8 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 are pivotable by a horizontal movement mechanism 13. The horizontal movement mechanism 13 moves the pair of transfer arms 11 horizontally between a transfer operation position (a position indicated by solid lines in FIG. 7) in which a semiconductor wafer W is transferred to and from the holder 7 and a retracted position (a position indicated by dash-double-dot lines in FIG. 7) in which the transfer arms 11 do not overlap the semiconductor wafer W held by the holder 7 as seen in plan view. The transfer operation position is under the susceptor 74, and the retracted position is outside the susceptor 74. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 4 and 5) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the treatment chamber 6.

Referring again to FIG. 3, the heat treatment part 160 includes the radiation thermometer 20 and a pressure gauge 95 as measuring devices. The radiation thermometer 20 is provided obliquely below the semiconductor wafer W held by the susceptor 74. The radiation thermometer 20 is a wafer thermometer which receives the infrared radiation emitted from the lower surface of the semiconductor wafer W through the opening 78 of the susceptor 74 to measure the temperature of the semiconductor wafer W, based on the intensity of the infrared radiation. The pressure gauge 95 measures the pressure inside the treatment chamber 6. The radiation thermometer 20 and the pressure gauge 95 are shown inside the treatment chamber 6 in FIG. 3 for convenience of illustration, but are both mounted on the wall surface of the treatment chamber 6.

The flash lamp house 5 provided over the treatment chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash lamp house 5 further includes a lamp light radiation window 53 mounted to the bottom of the enclosure 51. The lamp light radiation window 53 forming the floor of the flash lamp house 5 is a plate-like quartz window made of quartz. The flash lamp house 5 is provided over the treatment chamber 6, whereby the lamp light radiation window 53 is opposed to the upper chamber window 63. The flash lamps FL direct flashes of light from over the treatment chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane.

Each of the xenon flash lamps FL includes a rod-shaped glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second.

A flash power supply for supplying power to each of the flash lamps FL includes an IGBT (insulated-gate bipolar transistor) in addition to the aforementioned capacitor. By adjusting the waveform of the pulse applied to the gate of the IGBT, the light emission time of the flash lamps FL is definable between 0.1 and 100 milliseconds.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen lamp house 4 provided under the treatment chamber 6 includes an enclosure 41 incorporating the multiple (in the present preferred embodiment, 40) halogen lamps HL. The halogen lamps HL direct light from under the treatment chamber 6 through the lower chamber window 64 toward the heat treatment space 65.

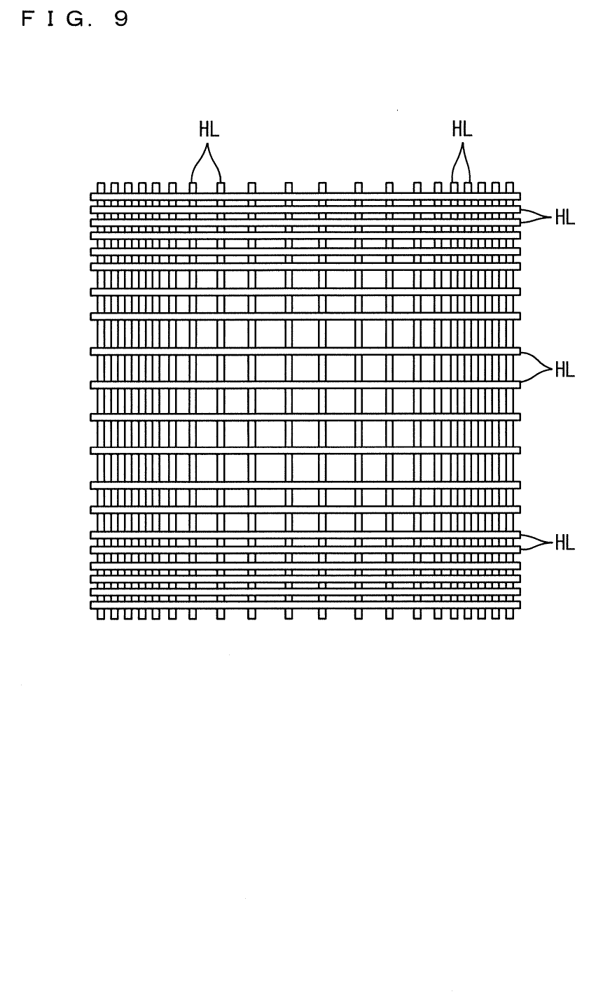

FIG. 9 is a plan view showing an arrangement of the multiple halogen lamps HL. In the present preferred embodiment, 20 halogen lamps HL are arranged in each of two tiers, i.e. upper and lower tiers. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 9, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen lamps HL.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the halogen lamps HL arranged in the upper tier and the longitudinal direction of the halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen lamp house 4 under the halogen lamps HL arranged in two tiers (FIG. 3). The reflector 43 reflects the light emitted from the halogen lamps HL toward the heat treatment space 65.

The heat treatment part 160 further includes, in addition to the aforementioned components, various cooling structures to prevent an excessive temperature rise in the halogen lamp house 4, the flash lamp house 5, and the treatment chamber 6 because of the heat energy generated from the halogen lamps HL and the flash lamps FL during the heat treatment of a semiconductor wafer W. As an example, a water cooling tube (not shown) is provided in the walls of the treatment chamber 6. Also, the halogen lamp house 4 and the flash lamp house 5 have an air cooling structure for forming a gas flow therein to exhaust heat. Air is supplied to a gap between the upper chamber window 63 and the lamp light radiation window 53 to cool down the flash lamp house 5 and the upper chamber window 63.

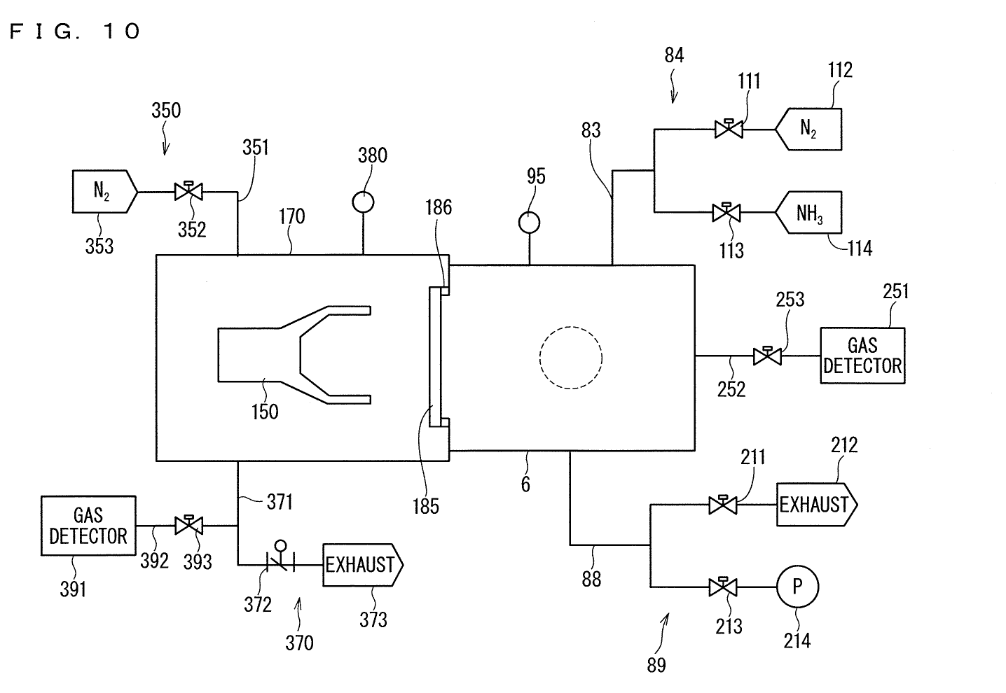

FIG. 10 is a diagram schematically showing supply and exhaust mechanisms for the treatment chamber 6 and the transport chamber 170. The treatment chamber 6 of the heat treatment part 160 is connected to one side of the transport chamber 170. The opening (the transport opening 66) which connects the treatment chamber 6 and the transport chamber 170 is opened and closed by the gate valve 185. When the gate valve 185 closes the transport opening 66, an O-ring 186 is sandwiched between the treatment chamber 6 and the transport chamber 170 to seal the interior space (the heat treatment space 65) of the treatment chamber 6. In other words, the treatment chamber 6 and the transport chamber 170 are connected via the gate valve 185 and the O-ring 186.

The gas supply part (a first gas supply part) 84 for supplying a treatment gas to the treatment chamber 6 includes valves 111 and 113, an inert gas supply source 112, and a reactive gas supply source 114. The gas supply pipe 83 has a distal end connected to the treatment chamber 6, and a proximal end bifurcated into two branch pipes. One of the branch pipes is connected to the inert gas supply source 112, and the other branch pipe is connected to the reactive gas supply source 114. The valve 111 is provided in the branch pipe connected to the inert gas supply source 112, and the valve 113 is provided in the branch pipe connected to the reactive gas supply source 114. When the valve 111 is opened, an inert gas (e.g., nitrogen) is supplied from the inert gas supply source 112 to the heat treatment space 65 in the treatment chamber 6. On the other hand, when the valve 113 is opened, a reactive gas (e.g., ammonia) is supplied from the reactive gas supply source 114 into the treatment chamber 6. That is, the gas supply part 84 supplies the reactive gas or the inert gas to the treatment chamber 6. By opening both the valve 111 and the valve 113, a mixture of the reactive gas and the inert gas may be supplied to the treatment chamber 6.

The exhaust part 89 for exhausting a gas from the treatment chamber 6 includes valves 211 and 213, an exhaust line 212, and a vacuum pump 214. The gas exhaust pipe 88 has a distal end connected to the treatment chamber 6, and a proximal end bifurcated into two branch pipes. One of the branch pipes is connected to the exhaust line 212, and the other branch pipe is connected to the vacuum pump 214. The exhaust line 212 is connected to an exhaust system provided in a factory in which the substrate processing apparatus 100 is installed. The valve 211 is provided in the branch pipe connected to the exhaust line 212, and the valve 213 is provided in the branch pipe connected to the vacuum pump 214. When the valve 211 is opened, the gas in the treatment chamber 6 is discharged to the exhaust line 212. On the other hand, when the valve 213 is opened while the vacuum pump 214 is operating, the gas is exhausted from the treatment chamber 6, so that the pressure in the treatment chamber 6 is reduced to less than atmospheric pressure. That is, the exhaust part 89 includes the vacuum pump 214 which exhausts the gas from the treatment chamber 6 to reduce the pressure in the treatment chamber 6 to less than atmospheric pressure.

The treatment chamber 6 is provided with the pressure gauge (a first pressure gauge) 95. The pressure gauge 95 measures the pressure of the gas in the treatment chamber 6.

Further, a gas detector (a first gas detector) 251 is connected via a sampling pipe 252 to the treatment chamber 6. A valve 253 is provided in the sampling pipe 252. When the valve 253 is opened, the gas in the treatment chamber 6 flows into the gas detector 251, whereby the concentration of the reactive gas in the treatment chamber 6 is measured. The gas detector 251 may be provided with a pump for suctioning the gas in the treatment chamber 6.

On the other hand, a gas supply part (a second gas supply part) 350 is connected via a gas supply pipe 351 to the transport chamber 170. The gas supply part 350 includes a valve 352 and an inert gas supply source 353. The gas supply pipe 351 has a distal end connected to the transport chamber 170, and a proximal end connected to the inert gas supply source 353. The valve 352 is interposed in the gas supply pipe 351. When the valve 352 is opened, an inert gas (e.g., nitrogen) is supplied from the inert gas supply source 353 to the transport chamber 170. That is, the gas supply part 350 supplies the inert gas to the transport chamber 170.

An exhaust part 370 is connected via a gas exhaust pipe 371 to the transport chamber 170. The exhaust part 370 for the transport chamber 170 includes a pressure regulating valve 372 and an exhaust line 373. The gas exhaust pipe 371 has a distal end connected to the transport chamber 170, and a proximal end connected to the exhaust line 373. The pressure regulating valve 372 is interposed in the gas exhaust pipe 371. The exhaust line 373 is connected to an exhaust system provided in the factory in which the substrate processing apparatus 100 is installed. The pressure regulating valve 372 controls the exhaust flow rate so as to maintain the pressure of the gas in the transport chamber 170 at a predetermined constant value. This causes the exhaust part 370 to exhaust the gas from the transport chamber 170 so as to ensure a constant pressure in the transport chamber 170.

A gas detector (a second gas detector) 391 is connected via a sampling pipe 392 to an intermediate portion of the path of the gas exhaust pipe 371. The sampling pipe 392 is connected to a portion of the path of the gas exhaust pipe 371 which is between the transport chamber 170 and the pressure regulating valve 372. A valve 393 is provided in the sampling pipe 392. When the valve 393 is opened, the gas in the transport chamber 170 flows from the gas exhaust pipe 371 through the sampling pipe 392 into the gas detector 391, whereby the concentration of the reactive gas in the transport chamber 170 is measured. The gas detector 391 may be provided with a pump for suctioning the gas from the gas exhaust pipe 371.

The transport chamber 170 is provided with a pressure gauge (a second pressure gauge) 380. The pressure gauge 380 measures the pressure of the gas in the transport chamber 170.

The controller 3 controls the aforementioned various operating mechanisms provided in the substrate processing apparatus 100. The controller 3 is shown in the indexer part 101 in FIG. 1. The present invention, however, is not limited to this. The controller 3 may be disposed in any position in the substrate processing apparatus 100.

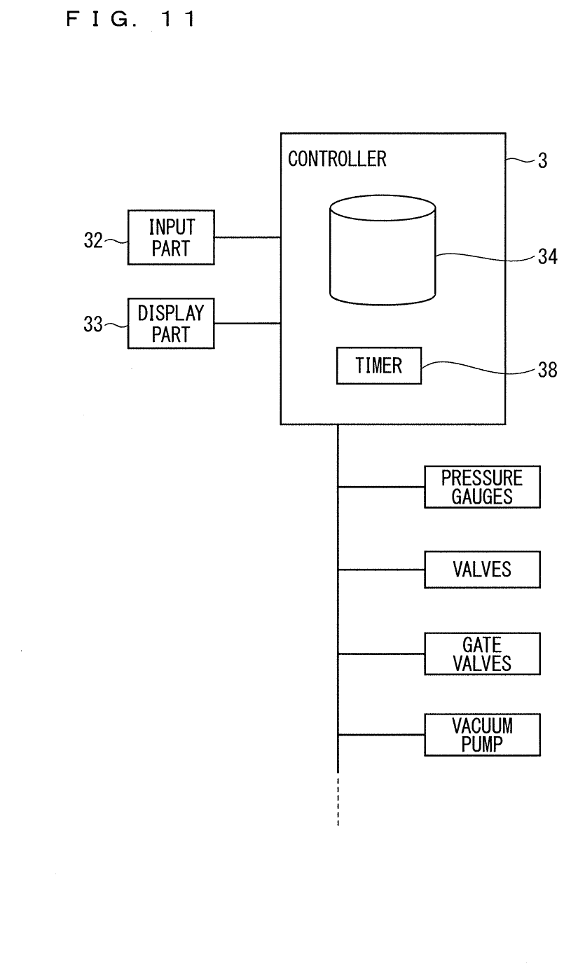

FIG. 11 is a block diagram showing a configuration of the controller 3. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a storage part 34 (e.g., a magnetic disk or an SSD) for storing control software, data and the like thereon. The CPU in the controller 3 executes a predetermined processing program, whereby the processes in the substrate processing apparatus 100 proceed. The controller 3 is further provided with a timer 38 having a timing function.

The controller 3 is electrically connected to components including the pressure gauges 95 and 380, the various valves, the gate valve 185, the vacuum pump 214, and the like. Measurement results from the pressure gauges 95 and 380 are transmitted to the controller 3. The controller 3 controls the operations of the gas supply part 84, the exhaust part 89 including the vacuum pump 214, and the gas supply part 350.

The controller 3 is also connected to a display part 33 and an input part 32. The display part 33 and the input part 32 function as a user interface for the substrate processing apparatus 100. The controller 3 causes a variety of pieces of information to appear on the display part 33. An operator of the substrate processing apparatus 100 may input various commands and parameters from the input part 32 while viewing the information appearing on the display part 33. A keyboard and a mouse, for example, may be used as the input part 32. A liquid crystal display, for example, may be used as the display part 33. In the present preferred embodiment, a liquid crystal touch panel provided on an outer wall of the substrate processing apparatus 100 is used to function as both the display part 33 and the input part 32. Thus, the display part 33 and the input part 32 constitute a GUI (Graphical User Interface) in the substrate processing apparatus 100.

Next, a processing operation in the substrate processing apparatus 100 according to the present invention will be described. A procedure for processing in the substrate processing apparatus 100 which will be described below proceeds under the control of the controller 3 over the operating mechanisms of the substrate processing apparatus 100.

First, while being stored in a carrier C, unprocessed semiconductor wafers (product wafers) W are placed on the first load port 110a or the second load port 110b of the indexer part 101. The transfer robot 120 takes the unprocessed semiconductor wafers W one by one out of the carrier C to transport each of the unprocessed semiconductor wafers W into the alignment chamber 231 of the alignment part 230. In the alignment chamber 231, a semiconductor wafer W is rotated in a horizontal plane about a vertical axis passing through the central portion of the semiconductor wafer W, and a notch or the like is optically detected, whereby the orientation of the semiconductor wafer W is adjusted.

Next, the transfer robot 120 of the indexer part 101 takes the orientation-adjusted semiconductor wafer W out of the alignment chamber 231 to transport the semiconductor wafer W into the first cool chamber 131 of the first cooling part 130 or the second cool chamber 141 of the second cooling part 140. In the present preferred embodiment, it is assumed that the semiconductor wafer W is transported into the first cool chamber 131 in the description below, but the same applies when the semiconductor wafer W is transported into the second cool chamber 141. The first cool chamber 131 temporarily holds the unprocessed semiconductor wafer W to be transported to the transport chamber 170. Then, the semiconductor wafer W in first cool chamber 131 is transported to the transport chamber 170 by the transport robot 150. The first cool chamber 131 and the second cool chamber 141 function as paths for transferring the semiconductor wafer W when the unprocessed semiconductor wafer W is transferred from the indexer part 101 via the first cool chamber 131 or the second cool chamber 141 to the transport chamber 170.

After taking the semiconductor wafer W out of the first cool chamber 131, the transport robot 150 pivots so as to face toward the treatment chamber 6 of the heat treatment part 160. Subsequently, the gate valve 185 opens the opening between the treatment chamber 6 and the transport chamber 170. Then, the transport robot 150 transports the unprocessed semiconductor wafer W into the treatment chamber 6. At this time, if a preceding semiconductor wafer W subjected to the heating treatment is present in the treatment chamber 6, the unprocessed semiconductor wafer W is transported into the treatment chamber 6 after one of the transport hands 151a and 151b takes out the semiconductor wafer W subjected to the heating treatment. In this manner, the semiconductor wafers W are interchanged. Thereafter, the gate valve 185 closes the opening between the treatment chamber 6 and the transport chamber 170.

The semiconductor wafer W transported into the treatment chamber 6 is preheated by the halogen lamps HL, and is thereafter subjected to the flash heating treatment by flash irradiation from the flash lamps FL. The flash heating treatment in the present preferred embodiment is carried out, for example, in a reduced-pressure ammonia atmosphere.

After the completion of the flash heating treatment, the gate valve 185 opens the opening between the treatment chamber 6 and the transport chamber 170 again. Then, the transport robot 150 transports the semiconductor wafer W subjected to the flash heating treatment from the treatment chamber 6 to the transport chamber 170. After taking out the semiconductor wafer W, the transport robot 150 pivots from the treatment chamber 6 so as to face toward the first cool chamber 131 or the second cool chamber 141. The gate valve 185 closes the opening between the treatment chamber 6 and the transport chamber 170.

Thereafter, the transport robot 150 transports the semiconductor wafer W subjected to the heating treatment into the first cool chamber 131 of the first cooling part 130 or the second cool chamber 141 of the second cooling part 140. In the present preferred embodiment, it is assumed that the semiconductor wafer W subjected to the heating treatment is transported into the second cool chamber 141 in the description below, but the same applies when the semiconductor wafer W subjected to the heating treatment is transported into the first cool chamber 131. The second cool chamber 141 temporarily holds and cools the semiconductor wafer W subjected to the heating treatment and transported from the transport chamber 170. The semiconductor wafer W is cooled to near room temperatures in the second cool chamber 141 because the temperature of the entire semiconductor wafer W is relatively high when the semiconductor wafer W is transported out of the treatment chamber 6 of the heat treatment part 160.

After a predetermined cooling time period has elapsed, the transfer robot 120 transports the cooled semiconductor wafer W out of the second cool chamber 141, and returns the cooled semiconductor wafer W back to the carrier C. After a predetermined number of processed semiconductor wafers W are stored in the carrier C, the carrier C is transported from the first load port 110a or the second load port 110b of the indexer part 101 to the outside.

The description on the heating treatment in the heat treatment part 160 will be continued. Prior to the treatment of the semiconductor wafer W, the valve 111 for supply of gas is opened, and the valve 211 for exhaust of gas is opened, so that the supply and exhaust of gas into and out of the treatment chamber 6 start. When the valve 111 is opened, nitrogen gas is supplied through the gas supply opening 81 into the heat treatment space 65. When the valve 211 is opened, the gas within the treatment chamber 6 is exhausted through the gas exhaust opening 86. This causes the nitrogen gas supplied from an upper portion of the heat treatment space 65 in the treatment chamber 6 to flow downwardly and then to be exhausted from a lower portion of the heat treatment space 65.

Subsequently, the gate valve 185 is opened to open the transport opening 66. The transport robot 150 transports an unprocessed semiconductor wafer W through the transport opening 66 into the heat treatment space 65 of the treatment chamber 6. The transport robot 150 moves the transport hand 151a (or the transport hand 151b) holding the unprocessed semiconductor wafer W forward to a position lying immediately over the holder 7, and stops the transport hand 151a (or the transport hand 151b) thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the unprocessed semiconductor wafer W is placed on the lift pins 12, the transport robot 150 causes the transport hand 151a to move out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface to be subjected to the flash heating treatment is the upper surface. A predetermined distance is defined between the back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is transported into the treatment chamber 6 and the transport opening 66 is closed by the gate valve 185 to cause the heat treatment space 65 to become an enclosed space, the pressure in the treatment chamber 6 is reduced to less than atmospheric pressure. Specifically, the valves 111 and 211 are closed, and the valve 213 is opened, while the vacuum pump 214 is operating, to exhaust the gas in the treatment chamber 6, thereby reducing the pressure in the treatment chamber 6 to a treatment pressure that is less than atmospheric pressure. The treatment pressure may be set to any appropriate value depending on the details of processes, but is typically between 100 Pa and 5000 Pa, for example.

While the pressure in the treatment chamber 6 is reduced, the valve 113 is opened to supply ammonia into the treatment chamber 6. At this time, the valve 111 may be opened simultaneously to supply a gas mixture of ammonia and nitrogen into the treatment chamber 6. This forms a reduced-pressure ammonia atmosphere in the heat treatment space 65 of the treatment chamber 6. If the exhaust flow rate of the gas from the exhaust part 89 is higher than the supply flow rate of the gas from the gas supply part 84, an ammonia atmosphere can be formed in the treatment chamber 6 while the pressure in the treatment chamber 6 is reduced.

After the pressure in the treatment chamber 6 is reduced to the predetermined treatment pressure and the ammonia atmosphere is formed in the treatment chamber 6, the 40 halogen lamps HL turn on simultaneously to start preheating (or assist-heating). Halogen light emitted from the halogen lamps HL is transmitted through the lower chamber window 64 and the susceptor 74 both made of quartz, and impinges upon the lower surface of the semiconductor wafer W. By receiving light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W is measured by the radiation thermometer 20 when the halogen lamps HL perform the preheating. Specifically, the radiation thermometer 20 receives infrared radiation emitted from the lower surface of the semiconductor wafer W held by the susceptor 74 through the opening 78 to measure the temperature of the semiconductor wafer W which is on the increase. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured by the radiation thermometer 20.

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured by the radiation thermometer 20 reaches the preheating temperature T1, the controller 3 adjusts the output from the halogen lamps HL to maintain the temperature of the semiconductor wafer W at approximately the preheating temperature T1.

By performing such preheating using the halogen lamps HL, the temperature of the entire semiconductor wafer W is uniformly increased to the preheating temperature T1. In the stage of preheating using the halogen lamps HL, the semiconductor wafer W shows a tendency to be lower in temperature in a peripheral portion thereof where heat dissipation is liable to occur than in a central portion thereof. However, the halogen lamps HL in the halogen lamp house 4 are disposed at a higher density in the region opposed to the peripheral portion of the semiconductor wafer W than in the region opposed to the central portion thereof. This causes a greater amount of light to impinge upon the peripheral portion of the semiconductor wafer W where heat dissipation is liable to occur, thereby providing a uniform in-plane temperature distribution of the semiconductor wafer W in the stage of preheating.

The flash lamps FL irradiate the front surface of the semiconductor wafer W with a flash of light at the point in time when a predetermined time period has elapsed since the temperature of the semiconductor wafer W reached the preheating temperature T1. At this time, part of the flash of light emitted from the flash lamps FL travels directly toward the interior of the treatment chamber 6. The remainder of the flash of light is reflected once from the reflector 52, and then travels toward the interior of the treatment chamber 6. The irradiation of the semiconductor wafer W with such flashes of light achieves the flash heating of the semiconductor wafer W.

The flash heating, which is achieved by the emission of a flash of light from the flash lamps FL, is capable of increasing the front surface temperature of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The front surface of the semiconductor wafer W is irradiated with such a flash of light which is extremely short in irradiation time and high in intensity, whereby the front surface temperature of the semiconductor wafer W momentarily increases to a treatment temperature T2. The treatment temperature T2 is higher than the preheating temperature T1. Upon reaching the treatment temperature T2, the front surface temperature of the semiconductor wafer W then decreases rapidly. The flash heating of the semiconductor wafer W in an ammonia atmosphere causes surface treatment (e.g., nitriding) to be performed on the semiconductor wafer W.

After a predetermined time period has elapsed since the completion of the flash heating treatment, the halogen lamps HL turn off. This causes the temperature of the semiconductor wafer W to decrease rapidly from the preheating temperature T1. The radiation thermometer 20 measures the temperature of the semiconductor wafer W which is on the decrease. The result of measurement is transmitted to the controller 3. After the completion of the flash heating treatment, the valves 113 and 213 are closed, and the valves 111 and 211 are opened. This causes ammonia to be gradually discharged from the treatment chamber 6. Thus, the ammonia atmosphere is replaced with a nitrogen atmosphere, and the pressure in the treatment chamber 6 is returned to atmospheric pressure.

After the pressure in the treatment chamber 6 is returned to atmospheric pressure, the controller 3 monitors whether the temperature of the semiconductor wafer W is decreased to a predetermined temperature or not, based on the result of measurement by means of the radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport hand 151b (or the transport hand 151a) of the transport robot 150 transports the heat-treated semiconductor wafer W placed on the lift pins 12 to the transport chamber 170. Thus, the treatment in the heat treatment part 160 is completed.

For the heating treatment of the semiconductor wafer W in the heat treatment part 160, the light irradiation is performed on the semiconductor wafer W while the pressure in the treatment chamber 6 is reduced to less than atmospheric pressure and the ammonia atmosphere is formed in the treatment chamber 6. On the other hand, the pressure in the transport chamber 170 is continuously maintained at atmospheric pressure while the heating treatment is performed on the semiconductor wafer W in the heat treatment part 160. That is, there arises a difference between the pressure in the treatment chamber 6 and the pressure in the transport chamber 170. However, the transport opening 66 connecting the treatment chamber 6 and the transport chamber 170 is closed by the gate valve 185, and the space between the gate valve 185 and the transport opening 66 is sealed by the O-ring 186. This precludes the gas from flowing from the transport chamber 170 in which pressure is relatively high into the treatment chamber 6 in which pressure is relatively low, and prevents hazardous ammonia in the treatment chamber 6 from leaking into the transport chamber 170.

However, if the O-ring 186 breaks, there is a danger that an abrupt gas movement from the transport chamber 170 to the treatment chamber 6 occurs to cause a pressure drop in the transport chamber 170, thereby resulting in the breakage of the quartz window 173. The quartz window 173 is relatively thin because the use of the quartz window 173 in a reduced-pressure condition is not assumed, whereas the upper and lower chamber windows 63 and 64 of the treatment chamber 6 are significantly thick and designed to be resistant to pressure. Additionally, if the O-ring 186 breaks, it is also contemplated that ammonia in the treatment chamber 6 leaks into the transport chamber 170.

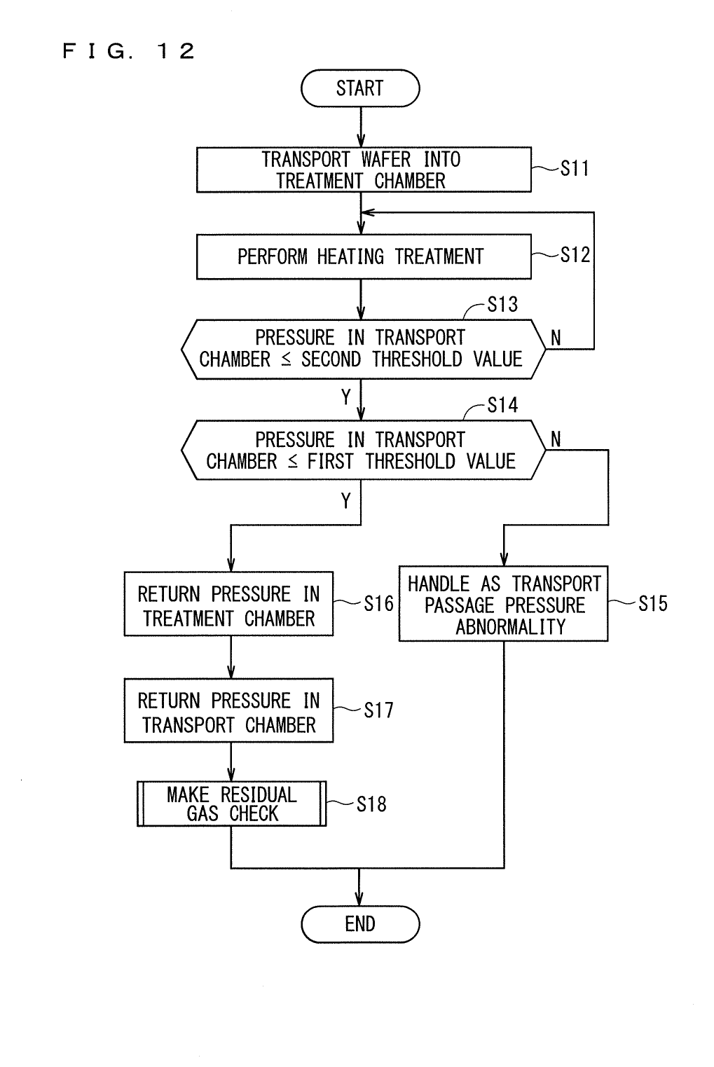

In the present preferred embodiment, measures to be described below are taken against the breakage of the O-ring 186. FIG. 12 is a flow diagram showing a procedure for pressure control in the case of the breakage of the O-ring 186. First, the transport robot 150 transports an unprocessed semiconductor wafer W into the treatment chamber 6, as mentioned above (Step S11). Then, the heating treatment is performed on the semiconductor wafer W in the treatment chamber 6 in accordance with the aforementioned procedure (Step S12). During the heating treatment, the light irradiation is performed on the semiconductor wafer W while the pressure in the treatment chamber 6 is reduced to less than atmospheric pressure and the ammonia atmosphere is formed in the treatment chamber 6.

While the heating treatment is performed on the semiconductor wafer W in the treatment chamber 6, the pressure gauge 380 measures the pressure of the gas in the transport chamber 170. The controller 3 monitors whether the value of the pressure in the transport chamber 170 which is measured by the pressure gauge 380 is greater than predetermined threshold values or not (Steps S13 and S14). If no particular abnormality occurs, the pressure in the transport chamber 170 is maintained generally at atmospheric pressure by the pressure regulating valve 372. If the pressure in the transport chamber 170 which is measured by the pressure gauge 380 is greater than a second threshold value Th2, the procedure returns from Step S13 to Step S12, and the heating treatment is continued. The second threshold value Th2 is, for example, a value that is 1 kPa lower than atmospheric pressure.

On the other hand, if the value measured by the pressure gauge 380 is not greater than the second threshold value Th2, the procedure proceeds from Step S13 to Step 14, in which the controller 3 compares the pressure in the transport chamber 170 with a first threshold value Th1. The first threshold value Th1 is, for example, a value that is 5 kPa lower than atmospheric pressure.

If the pressure in the transport chamber 170 which is measured by the pressure gauge 380 is not greater than the second threshold value Th2 and is greater than the first threshold value Th1, the procedure proceeds from Step S14 to Step S15, in which the result is handled as a transport passage pressure abnormality. In such a case, a slight pressure abnormality occurs in the transport chamber 170, and it is contemplated that the cause is an abnormality in the exhaust part 370 and the like, rather than the breakage of the O-ring 186. For example, if an abnormality occurs in factory exhaust connected to the exhaust line 373, a slight pressure abnormality occurs in the transport chamber 170 even without the breakage of the O-ring 186.

When the procedure proceeds to Step S15, the heating treatment of the semiconductor wafer W being performed in the treatment chamber 6 continues without any change. Thus, the processes necessary for the semiconductor wafer W are completed. This prevents processing failures. However, after the semiconductor wafer W subjected to the series of heating processes is transported out of the treatment chamber 6, the controller 3 prohibits its subsequent semiconductor wafer W from being transported into the treatment chamber 6. Thereafter, a checking operation of the exhaust part 370, for example, is performed.

On the other hand, if the pressure in the transport chamber 170 which is measured by the pressure gauge 380 is not greater than the first threshold value Th1, the procedure proceeds from Step S14 to Step 16, in which the process of returning the pressure in the treatment chamber 6 is performed. In such a case, there is a high likelihood that the breakage of the O-ring 186 has caused the gas in the transport chamber 170 to be abruptly sucked in by the treatment chamber 6 which is in a reduced-pressure condition. For this reason, the heating treatment of the semiconductor wafer W in the treatment chamber 6 is immediately interrupted, and the process of returning the pressure in the treatment chamber 6 is performed.

Specifically, in the pressure returning process of Step S16, the controller 3 stops the vacuum pump 214 which is reducing the pressure in the treatment chamber 6, and closes the valve 213. This stops the pressure reduction in the treatment chamber 6. The controller 3 also closes the valve 113 to stop the supply of ammonia to the treatment chamber 6. Further, the controller 3 opens the valve 111 and the valve 211. This supplies nitrogen into the treatment chamber 6 to return the pressure in the treatment chamber 6 to atmospheric pressure. At the same time, hazardous ammonia is discharged from the treatment chamber 6, so that the atmosphere replacement from an ammonia atmosphere to a nitrogen atmosphere proceeds.

By stopping the pressure reduction in the treatment chamber 6 and supplying nitrogen into the treatment chamber 6 to return the pressure in the treatment chamber 6 to atmospheric pressure, the difference between the pressure in the treatment chamber 6 and the pressure in the transport chamber 170 is decreased, so that a strong pressure reduction in the transport chamber 170 is suppressed. As a result, the breakage of the quartz window 173 is prevented from occurring. It should be noted that the quartz window 173 is not broken even by the reduction in pressure in the transport chamber 170 to the first threshold value Th1 (in the present preferred embodiment, atmospheric pressure minus 5 kPa) in Step S14.

In the present preferred embodiment, the process of returning the pressure in the transport chamber 170 is also performed in parallel with the process of returning the pressure in the treatment chamber 6 (Step S17). Specifically, the controller 3 opens the valve 352 to continue the supply of nitrogen to the transport chamber 170. The pressure regulating valve 372 regulates the flow rate of the gas exhausted to the exhaust line 373 so that the pressure in the transport chamber 170 becomes atmospheric pressure. This supplies nitrogen also to the transport chamber 170 to return the pressure in the transport chamber 170 to atmospheric pressure. By returning not only the pressure in the treatment chamber 6 but also the pressure in the transport chamber 170 to atmospheric pressure, the difference between the pressure in the treatment chamber 6 and the pressure in the transport chamber 170 is further decreased, so that the strong pressure reduction in the transport chamber 170 is prevented with higher reliability.

The heating treatment of the semiconductor wafer W is interrupted midway when it is judged in Step S14 that the pressure in the transport chamber 170 is not greater than the first threshold value Th1 even if the pressures in the treatment chamber 6 and the transport chamber 170 are returned to atmospheric pressure. Typically, such a semiconductor wafer W is in processing failure. This necessitates the retrieval of the semiconductor wafer W from the treatment chamber 6. It is hence necessary to open the gate valve 185. When the gate valve 185 is opened while ammonia remains in the treatment chamber 6, there is a danger that hazardous ammonia leaks from the treatment chamber 6 into the transport chamber 170. For this reason, the present preferred embodiment checks the concentration of the reactive gas remaining in the treatment chamber 6 (Step S18).

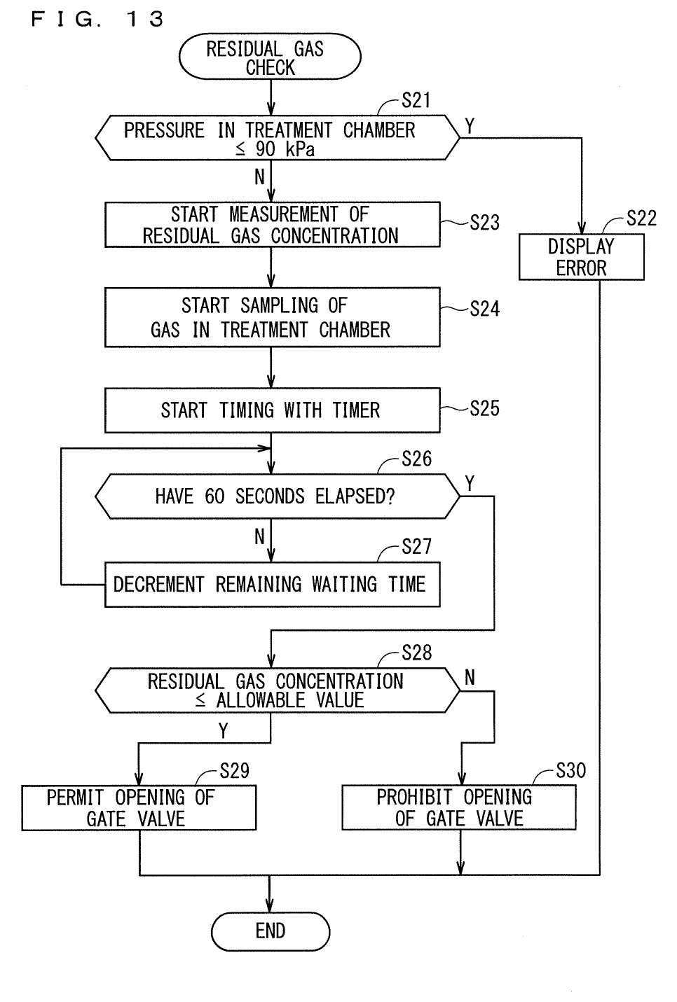

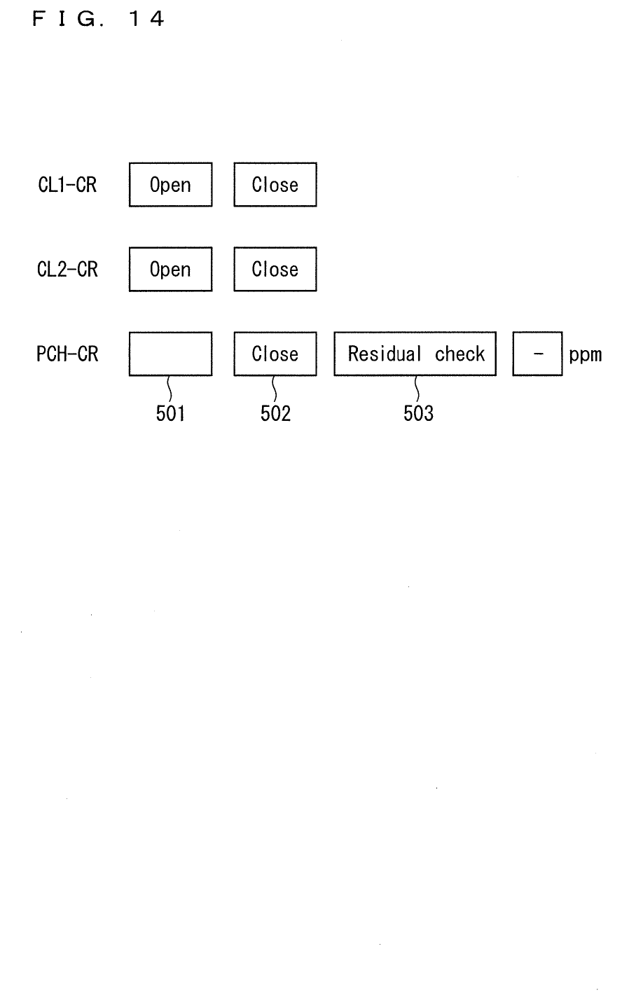

FIG. 13 is a flow diagram showing a procedure for the residual gas check in the treatment chamber 6. FIG. 14 is a view showing an example of a GUI appearing on the display part 33 (in the present preferred embodiment, a touch panel) during the residual gas check. In FIG. 14, "CL1-CR" represents the gate valve 183 between the first cool chamber 131 and the transport chamber 170; "CL2-CR" represents the gate valve 184 between the second cool chamber 141 and the transport chamber 170; and "PCH-CR" represents the gate valve 185 between the treatment chamber 6 and the transport chamber 170 (with reference to FIG. 1). For the gate valves 183 and 184, both "Open" and "Close" buttons are selectable. For the gate valve 185, on the other hand, prior to the execution of the residual gas check, a "Close" button 502 is selectable, but an "Open" button 501 is unselectable (e.g., grayed out). That is, the opening of the gate valve 185 is prohibited unless the check of the concentration of the reactive gas in the treatment chamber 6 has been performed even after the pressure in the treatment chamber 6 is returned to atmospheric pressure.

An operator of the substrate processing apparatus 100 selects and presses a "Residual check" button 503 from the GUI of FIG. 14, whereby the residual gas check in FIG. 13 starts. First, the pressure in the treatment chamber 6 is measured by the pressure gauge 95, and whether the measurement result is greater than 90 kPa or not is determined by the controller 3 (Step S21). If the pressure in the treatment chamber 6 is not greater than 90 kPa, the concentration is not measurable because the gas detector 251 cannot suck in the gas in the treatment chamber 6 even when the valve 253 is opened. For this reason, if the pressure in the treatment chamber 6 is not greater than 90 kPa, the procedure proceeds from Step S21 to Step S22, in which an error is displayed on the display part 33, and the residual gas check is stopped.

If the pressure in the treatment chamber 6 which is measured by the pressure gauge 95 is greater than 90 kPa, the procedure proceeds from Step S21 to Step S23, in which the measurement of the concentration of the reactive gas (in the present preferred embodiment, ammonia) remaining in the treatment chamber 6 starts. Specifically, the controller 3 opens the valve 253, and the gas detector 251 starts the sampling of the gas in the treatment chamber 6 (Step S24). The gas detector 251 measures the concentration of ammonia in the gas flowing thereinto from the treatment chamber 6. It should be noted that the valve 253 remains closed except during the sampling.

The timer 38 starts timing at the same time that the gas detector 251 starts the sampling (Step S25). The timer 38 performs timing for 60 seconds, for example (Step S26). If 60 seconds have not elapsed since the start of the timing with the timer 38, the procedure proceeds from Step S26 to Step S27, in which the remaining waiting time is decremented, and then the procedure returns to Step S26. In other words, a waiting state is entered in which Steps S26 and S27 are repeated until 60 seconds have elapsed since the start of the timing with the timer 38. It should be noted that the waiting time for the concentration measurement is not limited to 60 seconds, but may be set to any appropriate value.

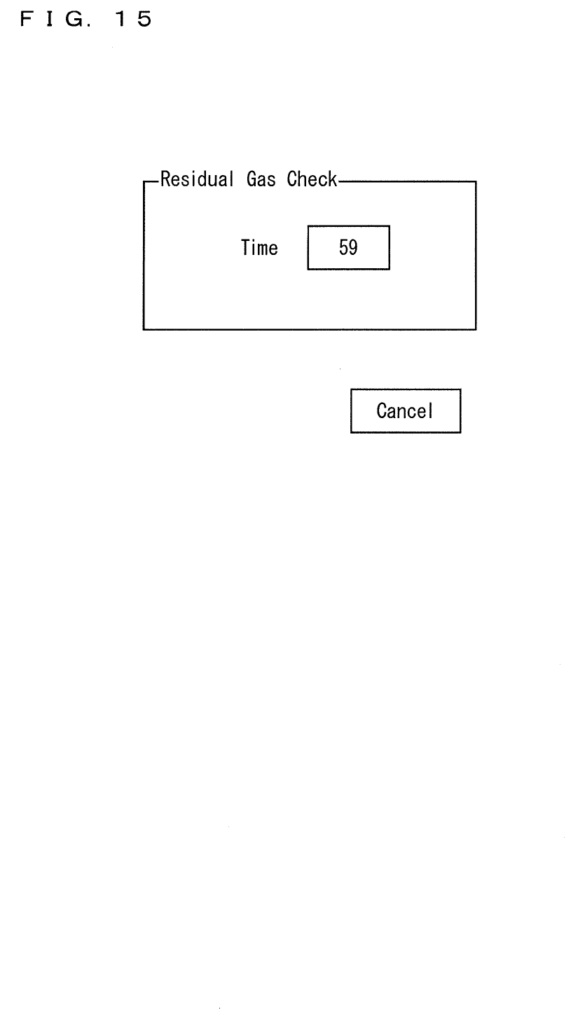

FIG. 15 is a view showing an example of the GUI appearing on the display part 33 during the concentration measurement waiting period. The remaining waiting time is displayed on the display part 33. When an operator presses a "Cancel" button, the valve 253 is closed and the concentration measurement is stopped.

The valves 111 and 211 remain open even during the concentration measurement waiting period. This causes nitrogen to be continuously supplied into the treatment chamber 6, and causes the gas in the treatment chamber 6 to be continuously exhausted. Thus, the concentration of ammonia remaining in the treatment chamber 6 gradually decreases even during the concentration measurement waiting period. The valves 113 and 213 are closed during the concentration measurement waiting period.

If 60 seconds have elapsed since the start of the timing with the timer 38, the procedure proceeds from Step S26 to Step S28. In Step S28, the controller 3 judges whether the concentration of ammonia remaining in the treatment chamber 6 which is measured by the gas detector 251 at that time is greater than an allowable value or not. If the concentration of ammonia remaining in the treatment chamber 6 is not greater than the allowable value, the procedure proceeds from Step S28 to Step S29, in which the controller 3 permits the opening of the gate valve 185.

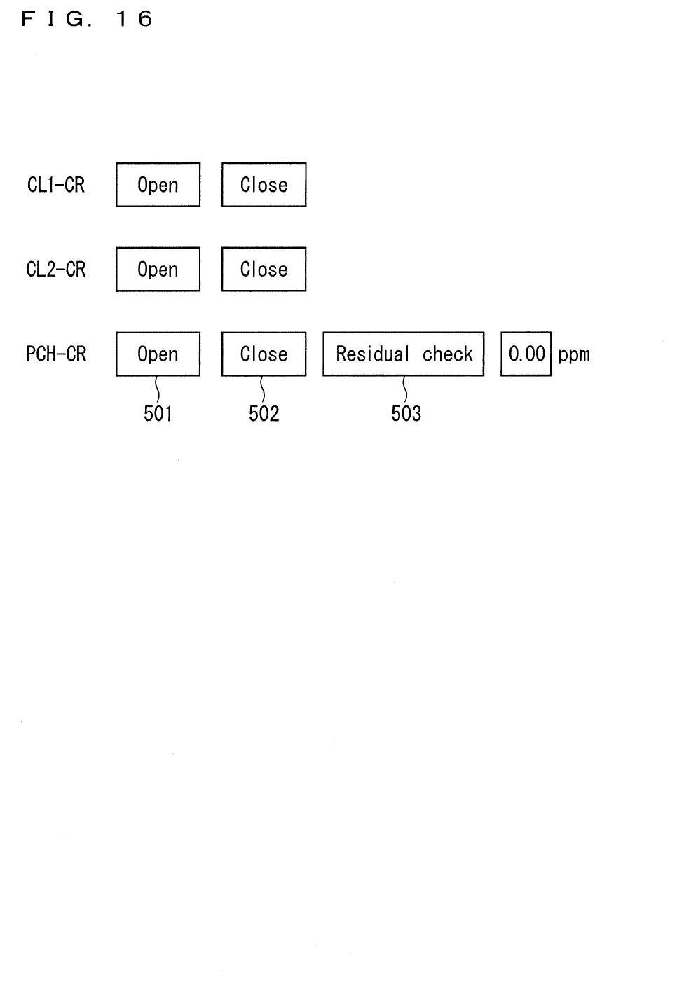

FIG. 16 is a view showing an example of the GUI appearing on the display part 33 when the opening of the gate valve 185 is permitted. A difference from FIG. 14 lies in that the "Open" button 501 for the gate valve 185 is displayed as selectable (the grayed-out state is cancelled). The concentration of ammonia measured by the gas detector 251 is also displayed. When an operator presses the "Open" button 501 for the gate valve 185, the gate valve 185 opens to allow the semiconductor wafer W whose treatment is interrupted to be taken out of the treatment chamber 6. Since the concentration of ammonia remaining in the treatment chamber 6 is not greater than the allowable value and is at a safe level, there is no danger that hazardous ammonia leaks from the treatment chamber 6 into the transport chamber 170 even when the gate valve 185 is opened.

On the other hand, if the concentration of ammonia remaining in the treatment chamber 6 which is measured by the gas detector 251 is greater than the allowable value, the procedure proceeds from Step S28 to Step S30, in which the controller 3 does not permit the opening of the gate valve 185. In this case, the display in FIG. 14 continues to appear on the display part 33. Thus, the operator cannot open the gate valve 185. This prevents ammonia from leaking from the treatment chamber 6 into the transport chamber 170 to ensure safety. In this case, the operator may press the "Residual check" button 503 again to repeat the residual gas check until the concentration of ammonia remaining in the treatment chamber 6 falls to not greater than the allowable value.

In the present preferred embodiment, the treatment chamber 6 for performing the heating treatment on the semiconductor wafer W and the transport chamber 170 for housing the transport robot 150 therein are connected to each other via the gate valve 185 and the O-ring 186. If the O-ring 186 breaks while the pressure in the treatment chamber 6 is reduced during the heating treatment of the semiconductor wafer W, there is a danger that an abrupt pressure drop occurs in the transport chamber 170. To prevent this, the present preferred embodiment monitors changes in gas pressure in the transport chamber 170 during the execution of the heating treatment of the semiconductor wafer W in the treatment chamber 6. Then, if the pressure in the transport chamber 170 falls to not greater than the second threshold value Th2, the result is handled as the transport passage pressure abnormality. Further, if the pressure in the transport chamber 170 falls to not greater than the first threshold value Th1, the heating treatment is interrupted, and the pressure regulation is performed on the treatment chamber 6 and the transport chamber 170 to return the pressures in the treatment chamber 6 and the transport chamber 170 to atmospheric pressure. In short, the pressures in the treatment chamber 6 and the transport chamber 170 are returned to atmospheric pressure immediately after the likelihood of the breakage of the O-ring 186 is detected,. This decreases the difference between the pressure in the treatment chamber 6 and the pressure in the transport chamber 170 to prevent the strong pressure reduction from occurring in the transport chamber 170, thereby preventing the breakage of the quartz window 173 and the like. That is, problems resulting from the breakage of the O-ring 186 which connects the treatment chamber 6 and the transport chamber 170 are mitigated.

In addition, the present preferred embodiment checks the concentration of the reactive gas remaining in the treatment chamber 6 before opening the gate valve 185 for the purpose of retrieving the semiconductor wafer W whose treatment is interrupted. The gate valve 185 is permitted to open if the concentration of the reactive gas remaining in the treatment chamber 6 is not greater than the allowable value as a result of the concentration measurement performed over the preset predetermined time period. Further, the opening of the gate valve 185 is prohibited unless the check of the concentration of the reactive gas remaining in the treatment chamber 6 has been performed. This prevents the hazardous reactive gas from leaking from the treatment chamber 6 into the transport chamber 170.

While the preferred embodiment according to the present invention has been described hereinabove, various modifications of the present invention in addition to those described above may be made without departing from the scope and spirit of the invention. For example, the pressure regulation is performed on both the treatment chamber 6 and the transport chamber 170 when the pressure in the transport chamber 170 falls to not greater than the first threshold value Th1 in the aforementioned preferred embodiment. However, the pressure regulation in both the treatment chamber 6 and the transport chamber 170 is not necessarily required, but it is sufficient to return the pressure in at least the treatment chamber 6 to atmospheric pressure. Returning the pressure in at least the treatment chamber 6 to atmospheric pressure decreases the pressure difference between the treatment chamber 6 and the transport chamber 170 to mitigate the problems resulting from the breakage of the O-ring 186. When returning the pressure in the treatment chamber 6 to atmospheric pressure, it is sufficient to stop at least the vacuum pump 214 and supply an inert gas into the treatment chamber 6.

In the aforementioned preferred embodiment, the concentration check of the reactive gas remaining in the treatment chamber 6 is made in Step S18. In addition to this check, a concentration check of the reactive gas remaining in the transport chamber 170 may be made. Normally, the reactive gas such as ammonia does not flow from the treatment chamber 6 into the transport chamber 170 during the heating treatment of the semiconductor wafer W because the pressure in the treatment chamber 6 is lower than the pressure in the transport chamber 170. However, if the O-ring 186 breaks, the reactive gas leaks into the transport chamber 170 in some cases. For the residual gas check in the transport chamber 170, the valve 393 is opened, and the gas detector 391 performs the sampling for 60 seconds from the gas exhaust pipe 371 and measures the concentration of the reactive gas, as in the residual gas check for the treatment chamber 6 (FIG. 13). Then, the controller 3 judges whether the concentration of the reactive gas remaining in the transport chamber 170 is greater than an allowable value or not.

Additionally, the residual gas check in the treatment chamber 6 may be made when it is necessary to open the gate valve 185, such as when the vacuum pump 214 malfunctions or when the semiconductor wafer W breaks during the flash irradiation.

In the layout of the substrate processing apparatus 100 shown in FIG. 1, a chamber for a flaw detection part for detecting flaws on the back surface of the semiconductor wafer W, for example, may be connected to the opposite side (the negative Y side) of the indexer part 101 from the alignment part 230.

In the aforementioned preferred embodiment, ammonia is used as the reactive gas during the heating treatment of the semiconductor wafer W. The present invention, however, is not limited thereto. Examples of the reactive gas hazardous when leaking out to the transport chamber 170 include ozone.

Although the 30 flash lamps FL are provided in the flash lamp house 5 in the aforementioned preferred embodiment, the present invention is not limited to this. Any number of flash lamps FL may be provided. The flash lamps FL are not limited to the xenon flash lamps, but may be krypton flash lamps. Also, the number of halogen lamps HL provided in the halogen lamp house 4 is not limited to 40. Any number of halogen lamps HL may be provided.

In the aforementioned preferred embodiment, the filament-type halogen lamps HL are used as continuous lighting lamps that emit light continuously for not less than one second to preheat the semiconductor wafer W. The present invention, however, is not limited to this. In place of the halogen lamps HL, discharge type arc lamps (e.g., xenon arc lamps) or LED lamps may be used as the continuous lighting lamps to perform the preheating.

While the invention has been shown and described in detail, the foregoing description is in all aspects illustrative and not restrictive. It is therefore understood that numerous modifications and variations can be devised without departing from the scope of the invention.

What is claimed is:

1. A method of heating a substrate by irradiating the substrate with light, comprising:
(a) transporting a substrate into a treatment chamber connected via a gate valve and an O-ring to a transport chamber for housing a transport robot;
(b) irradiating said substrate with light to perform a heating treatment while pressure in said treatment chamber which receives said substrate therein is reduced to less than atmospheric pressure and a predetermined reactive gas atmosphere is formed in said treatment chamber;
(c) detecting whether pressure in said transport chamber is greater than a first threshold value less than atmospheric pressure or not during the execution of said (b); and
(d) stopping an exhaust pump for reducing the pressure in said treatment chamber and supplying an inert gas into said treatment chamber to return the pressure in said treatment chamber to atmospheric pressure, when it is detected that the pressure in said transport chamber is not greater than said first threshold value.

2. The method according to claim 1,
wherein, when it is detected that the pressure in said transport chamber is not greater than said first threshold value, the inert gas is further supplied into said transport chamber to return the pressure in said transport chamber to atmospheric pressure.

3. The method according to claim 1,
wherein, when it is detected in said (c) that the pressure in said transport chamber is not greater than a second threshold value higher than said first threshold value, the transport of a subsequent substrate into said treatment chamber is stopped while said (b) is continued, and
wherein, when it is detected in said (c) that the pressure in said transport chamber is not greater than said first threshold value, said (d) is executed.

4. The method according to claim 1, further comprising
(e) measuring the concentration of said reactive gas remaining in said treatment chamber after the pressure in said treatment chamber is returned to atmospheric pressure in said (d),
wherein said gate valve is permitted to open if the concentration of said reactive gas in said treatment chamber is not greater than a predetermined value.

5. The method according to claim 4,
wherein said gate valve is prohibited from opening if said (e) is not executed after the pressure in said treatment chamber is returned to atmospheric pressure in said (d).

6. The method according to claim 4, further comprising
(f) measuring the concentration of said reactive gas in said transport chamber after the pressure in said treatment chamber is returned to atmospheric pressure in said (d).

7. A substrate processing apparatus for heating a substrate by irradiating the substrate with light, comprising:
a transport chamber for housing a transport robot;
a treatment chamber connected via a gate valve and an O-ring to said transport chamber;
a first gas supply part for supplying a predetermined reactive gas or inert gas to said treatment chamber;
an exhaust part including an exhaust pump for exhausting a gas from said treatment chamber to reduce pressure in said treatment chamber;
a light irradiator for irradiating a substrate received in said treatment chamber with light;
a first pressure gauge for measuring the pressure in said treatment chamber;
a second pressure gauge for measuring pressure in said transport chamber; and
a controller for controlling said first gas supply part and said exhaust part,
wherein, when it is detected that the pressure in said transport chamber measured by said second pressure gauge is not greater than a first threshold value less than atmospheric pressure during the execution of a heating treatment that irradiates said substrate with light while the pressure in said treatment chamber which receives said substrate therein is reduced to less than atmospheric pressure and an atmosphere of said reactive gas is formed in said treatment chamber, said controller stops said exhaust pump and controls said first gas supply part so as to supply the inert gas into said treatment chamber to thereby return the pressure in said treatment chamber to atmospheric pressure.

8. The substrate processing apparatus according to claim 7, further comprising
a second gas supply part for supplying an inert gas to said transport chamber,
wherein, when it is detected that the pressure in said transport chamber is not greater than said first threshold value, said controller controls said second gas supply part so as to supply the inert gas into said transport chamber to thereby return the pressure in said transport chamber to atmospheric pressure.

9. The substrate processing apparatus according to claim 7,
wherein, when it is detected that the pressure in said transport chamber measured by said second pressure gauge is not greater than a second threshold value higher than said first threshold value, the transport of a subsequent substrate into said treatment chamber is stopped while said heating treatment is continued.

10. The substrate processing apparatus according to claim 7, further comprising
a first gas detector for measuring the concentration of said reactive gas in said treatment chamber,
wherein said gate valve is permitted to open if the concentration of said reactive gas remaining in said treatment chamber is not greater than a predetermined value after the pressure in said treatment chamber is returned to atmospheric pressure.

11. The substrate processing apparatus according to claim 10,
wherein said gate valve is prohibited from opening if the measurement of the concentration of said reactive gas in said treatment chamber is not executed by said first gas detector after the pressure in said treatment chamber is returned to atmospheric pressure.

12. The substrate processing apparatus according to claim 10, further comprising
a second gas detector for measuring the concentration of said reactive gas in said transport chamber,
wherein said second gas detector measures the concentration of said reactive gas in said transport chamber after the pressure in said treatment chamber is returned to atmospheric pressure.
